(19) United States
(12) Patent Application Publication
(10) Pub. No.: US 2022/0174840 A1
(43) Pub. Date: Jun. 2, 2022

(54) COOLING ARRANGEMENT

(71) Applicant: YASA LIMITED, Kidlington, Oxfordshire (GB)

(72) Inventors: Simon David HART, Welshpool, Powys (GB); Rajesh KUDIKALA, Thatcham, Berkshire (GB)

(21) Appl. No.: 17/442,518

(22) PCT Filed: Mar. 24, 2020
(86) PCT No.: PCT/EP2020/058240

§ 371 Date: Sep. 23, 2021

(30) Foreign Application Priority Data
Mar. 29, 2019 (GB) 1904441.1

(51) Int. Cl. H05K 7/20; F28D 1/03; F28F 13/06; F28F 3/02

(52) U.S. Cl. CPC H05K 7/2089; H05K 7/20409; H05K 7/20263; F28D 2021/0029; F28F 13/06; F28F 3/022; F28D 1/0383

(57) ABSTRACT

A cooling arrangement, for cooling power devices such as semiconductor power devices, comprises a housing having sidewalls around the periphery of a baseplate, and a capping plate opposing the baseplate. The housing forms a cavity through which cooling fluid may flow between an inlet and an outlet disposed in the housing. Within the cavity is provided one or more baffles that are arranged to force the cooling fluid flowing between the inlet and outlet along a labyrinthine path through the cavity. At least one of the baffles comprises at least one through-hole, which permit cooling fluid to pass there through from one side of the baffle to the other.

### FIELD OF THE INVENTION

The present invention relates to cooling arrangements, in particular to cooling arrangement suitable for power semiconductors.

### BACKGROUND OF THE INVENTION

Power modules are widely used to control multi-phase electric machines in industry. In the past decade electric motors and generators have found increasing application as renewable energy supplies and in transportation as replacement or assistive traction units alongside IC engines.

The present invention is aimed at improving the range over which power supplies can be operated by more efficiently removing waste energy, in the form of heat.

Power modules are a convenient way of providing high density solutions for power semiconductor switches an important component of DC to multiphase AC and AC-DC power supplies. The high density of power semiconductor switches leads to a concentration of heat loss which raises the local temperature of components. A significant level of research and development effort has been focussed to remove waste heat so that power supplies can be operated to higher limits thereby increasing power density and improving machine reliability.

A leading heat removal solution employs a heatsink with pin fins attached. Fluid (typically water) is passed through a chamber into which power module pin fins protrude. Pin fin arrangements provide a large surface area and a low amount of turbulence and low amount of mixing which has been deemed the best available format for removal of heat, however prior art approaches used to date fail to fully utilise the heat capacity of flowing coolant and it has been determined that improvement can be made to increase the transfer of heat to the fluid.

Prior art means of heat removal are often compromised in their effectiveness because heat dissipating components are usually serially cooled by fluid and devices towards the end of the fluid traverse see hotter fluid and so are less effectively cooled. Devices towards the end of the fluid traverse hit their temperature limit first and overall module rating is limited by the hottest devices. Additionally, differential heat removal leads to dissimilar thermal stresses in power devices which can adversely affect lifetimes of power modules.

A significant variable for pin fin heat sinks is pressure drop between inlet manifold and outlet manifold caused by the pins themselves and exacerbated by deflection plates used to guide coolant fluid to low flow regions within the cooling cavity.

It the light of deficiencies of pin fin cooling offered in the prior art it is appreciated that there is a need for an improved way of cooling power semiconductors.

### SUMMARY OF THE INVENTION

According to the present invention, there is provided a cooling arrangement, comprising: a housing having a base plate, side walls around the periphery of the base plate, and a capping plate opposing the base plate, the base plate, side walls and capping plate being arranged to form a fluid-tight cavity through which a cooling fluid is flowable; an array of pins fins protruding from the base plate into the cavity; an inlet and an outlet in fluid communication with the cavity, the inlet and outlet being arranged such that cooling fluid flowing between the inlet and outlet is caused to flow through the cavity over the array of pin fins; and one or more baffles extending between the base plate and capping plate, and extending along a portion of the base plate between opposing side walls for providing a labyrinthine flow path for the cooling fluid when flowing through the cavity between the inlet and outlet, wherein at least one of the baffles comprises at least one through hole, through which cooling fluid is flowable from one side of the baffle to the other.

Advantageously, the provision of baffles with through holes provides a cooling arrangement having superior cooling capabilities compared to known cooling arrangements. The baffles provide for a meandering path for the cooling fluid, forcing the cooling fluid to pass over more of the pin fins, and the through holes in the baffles also provide a cooling advantage since more heat may be passed to the cooling fluid, and the through holes also help to reduce the pressure drop experienced by the cooling fluid between the inlet and outlet.

The cooling arrangement may comprise a plurality of holes in the respective baffle, the holes being arranged in an array along at least a portion of the length of the baffle. The array of holes may comprise two or more rows of holes. The rows of holes may be offset from one another.

In the cooling arrangement, the inlet and outlet may be located in the same sidewall of the housing, or the inlet and outlet may be located in the capping plate, opposing the base plate.

Alternatively, the inlet may be located in a first side wall, and the outlet may be located in a second side wall, different to the first side wall. The first and second side walls may oppose one another. The inlet and outlet my diagonally oppose one another.

The pin fins may be mounted on and thermally coupled to the base plate. The pin fins may also be attached to the capping plate.

Alternatively, the pin fins may extend from the base plate a portion of the distance towards the capping plate, wherein a gap is provided between the tip of the pin fins and the capping plate.

In either case, the pin fins may be cylindrical or tapered cylindrical.

Furthermore, a gap may be provided between the capping plate and the one or more baffles along at least a portion of the length of the baffle.

The holes may generally be circular or star shaped.

### LIST OF FIGURES

The present invention will be described, by way of example only, and with reference to the accompanying figures, in which:

FIG. 1 shows a housing of a cooling arrangement using a “U” flow arrangement;

FIG. 2 shows a housing of a cooling arrangement using a diagonal flow arrangement;

FIG. 3 shows an exploded view of the housing of FIG. 1 with the internal pin fins shown;

FIG. 4 shows the housing of FIG. 3 from the base plate side;

FIG. 5 shows an exploded view of the housing of FIG. 2 with the internal pin fins shown;

FIG. 6 shows the housing of FIG. 5 from the base plate side;

FIG. 7 shows a cooling arrangement comprising baffles;

FIG. 8 shows an alternative view of FIG. 7 without the pin fins being shown; and

FIG. 9 shows a cooling arrangement comprising baffles with holes.

### DETAILED DESCRIPTION OF THE PREFERRED EMBODIMENT

In brief, the present invention provides a cooling arrangement for cooling power devices such as power semiconductor devices. The cooling arrangement comprises a housing having sidewalls around the periphery of a baseplate, and a capping plate opposing the baseplate. The housing forms a cavity through which cooling fluid may flow between an inlet and an outlet disposed in the housing. Within the cavity is provided one or more baffles that are arranged to force the cooling fluid flowing between the inlet and outlet along a labyrinthine path through the cavity. At least one of the baffles comprises at least one through-hole of any shape, which permit cooling fluid to pass therethrough from one side of the baffle to the other.

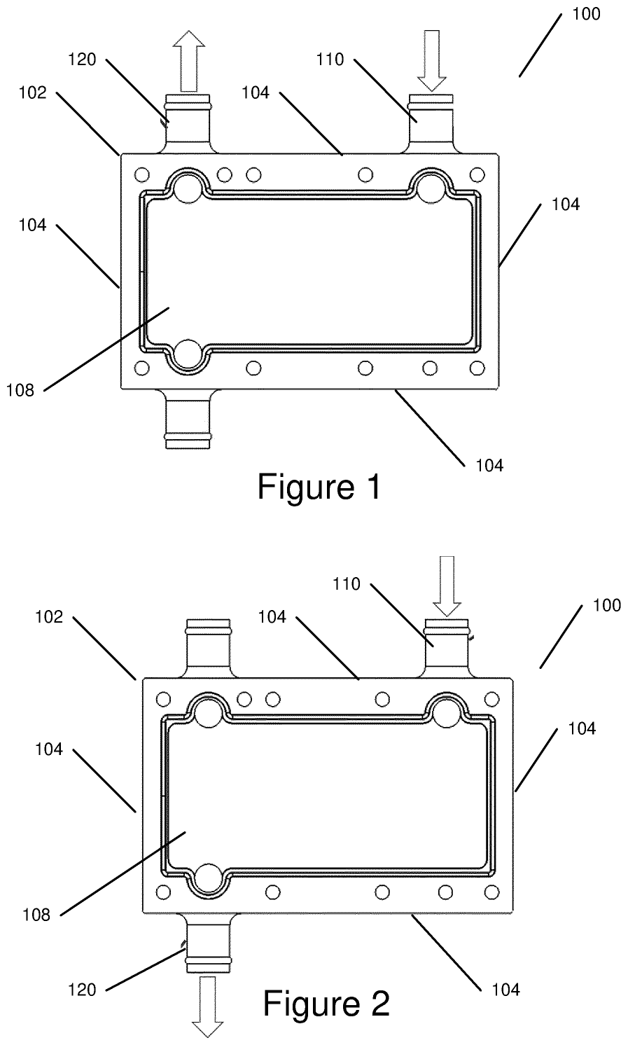

FIGS. 1 to 8 show known cooling arrangements that may be used to cool power devices, such as semiconductor power devices. Like references are used throughout, so the various arrangements will be discussed in turn.

The cooling arrangements (100) comprise a housing (102), which is formed from a base plate (106) surrounded around its periphery by side walls (104) and a capping plate (108) opposing the base plate (106).

This housing arrangement forms a cavity (130), in, and through, which cooling fluid may flow. An inlet (110) and an outlet (120) are provided in the housing (102) that are in fluid communication with the cavity (130) to permit the flow of cooling fluid between the inlet (110) and outlet (120) through the cavity (130).

Various arrangements of the inlet (110) and outlet (120) are envisaged. For example, FIG. 1 shows inlet (110) and outlet (120) in the same side wall (104), which provides a “U” flow arrangement. That is, the cooling fluid flowing between the inlet and outlet will tend to flow in a “U” shape as it flows through the cavity (130). For the “U” flow arrangement, the inlet (110) and outlet (120) need not be located in the side walls (104). They may, for example, be located in the capping plate (108).

FIG. 2 shows an alternative arrangement for a diagonal flow of cooling fluid. In FIG. 2, the inlet (110) and outlet (120) are disposed in opposing side walls (104) and diagonally offset from one another to provide an arrangement where the cooling fluid flowing between the inlet and outlet take a generally diagonal path through the cavity (130).

An alternative to FIG. 2 would be to have the inlet (110) and outlet (120) more centrally located in each of the respective side walls (104), opposing each other.

Within the cavity (130) is located an array of pin fins (140). These are pin fins that are mechanically and thermally coupled to the base plate (106) and protrude into the cavity (130). Through their thermal coupling with the base plate (106), heat is transferred from power device(s) thermally coupled to the base plate into the pin fins (140). When the cooling fluid is in contact with the pin fins (140), heat is transferred from the pin fins into the cooling fluid, which is then taken away as the cooling fluid flows through the cavity (130).

For the sake of simplicity, power devices that may be mounted to the base plate (106) are not shown. However, it would be apparent to those skilled in the art that power devices may be mounted mechanically and thermally to the exterior facing surface of the base plate (106) in order to cool the power devices.

It is known that in-line pin-fin arrays in comparison to off-set arrays offer lower flow resistance, but correspondingly increased thermal resistance between heat dissipating elements and coolant medium and in general the obverse is true. The shape of pins is a function of manufacturability and optimum surface to volume ratio whilst recognising that indents in pins may increase potential for stagnant fluid and poor heat transfer whilst detents are difficult to manufacture. In general, cylindrical or tapered cylindrical pin fins are preferred, although other formats may be used for manufacturing or heat transfer reasons.

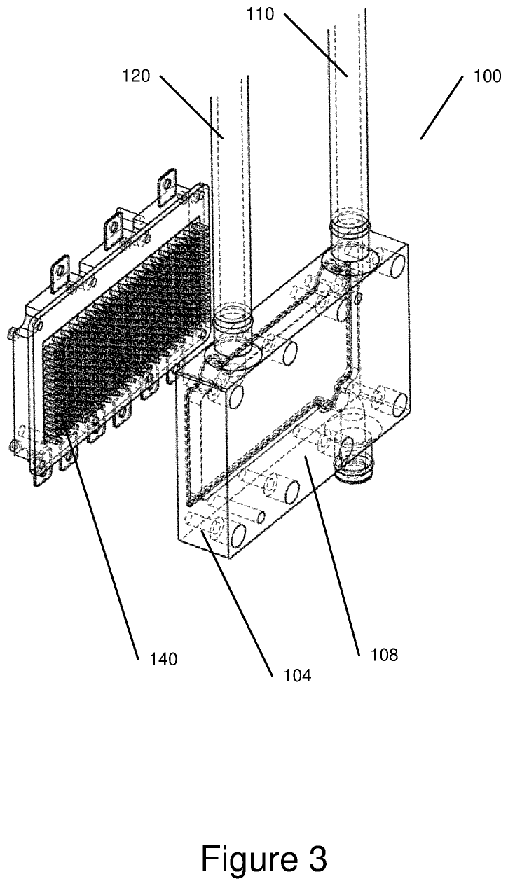

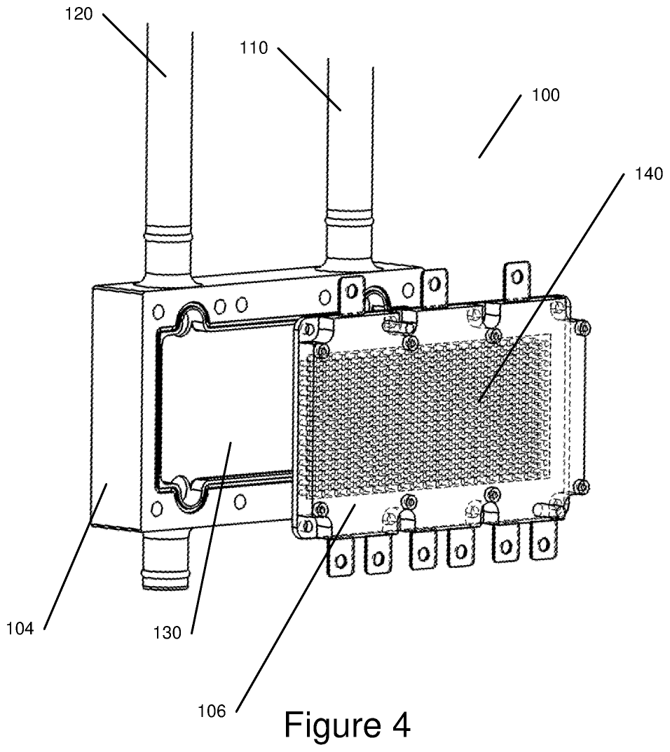

FIGS. 3 and 4 show an example cooling arrangements showing the pin fins through the housing with a “U” shaped flow arrangement of inlet (110) and outlet (120).

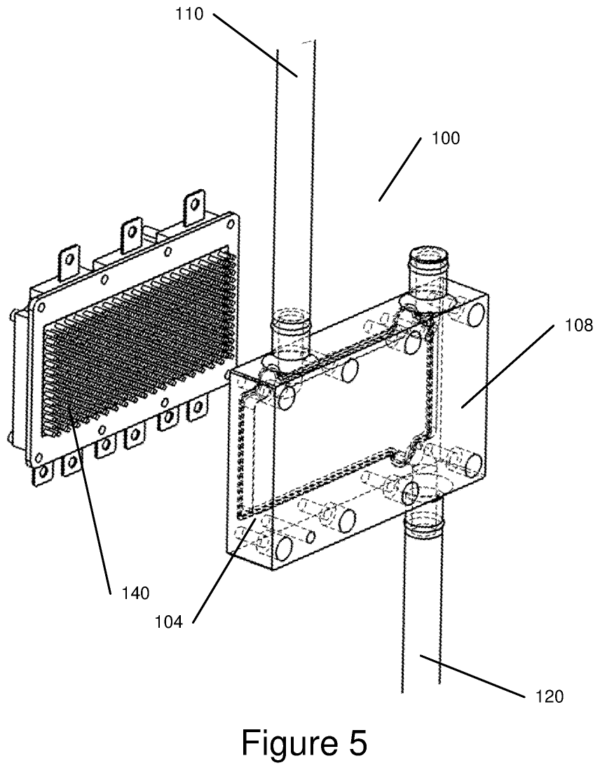

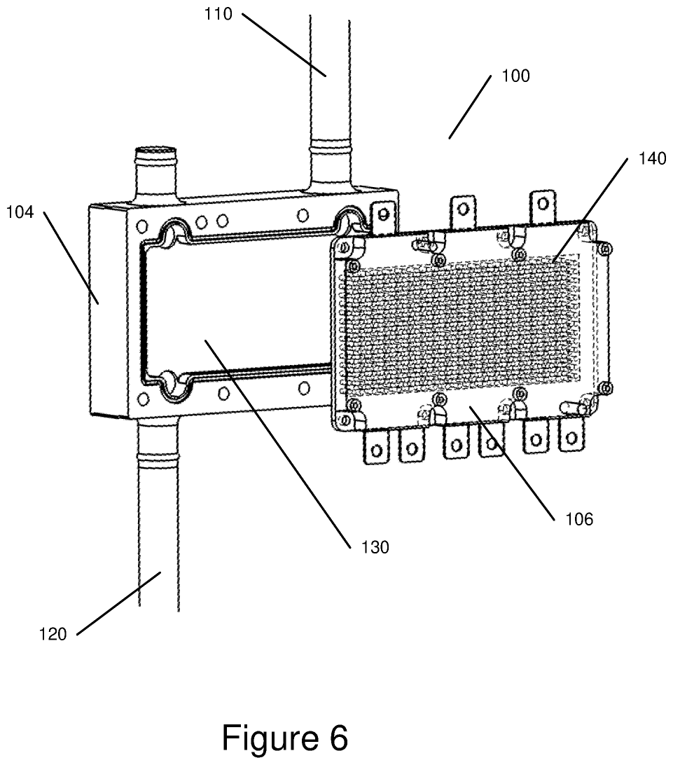

FIGS. 5 and 6 show an example cooling arrangements showing the pin fins through the housing with a diagonal flow arrangement of inlet (110) and outlet (120).

Surprisingly, it has been found that the diagonal flow arrangement is capable of extracting more heat from the pin fins (140) than the “U”-shaped flow arrangement, that is the cooling arrangement utilising the diagonal flow is capable of cooling the devices better or more efficiently than that of the “U”-shaped flow arrangement.

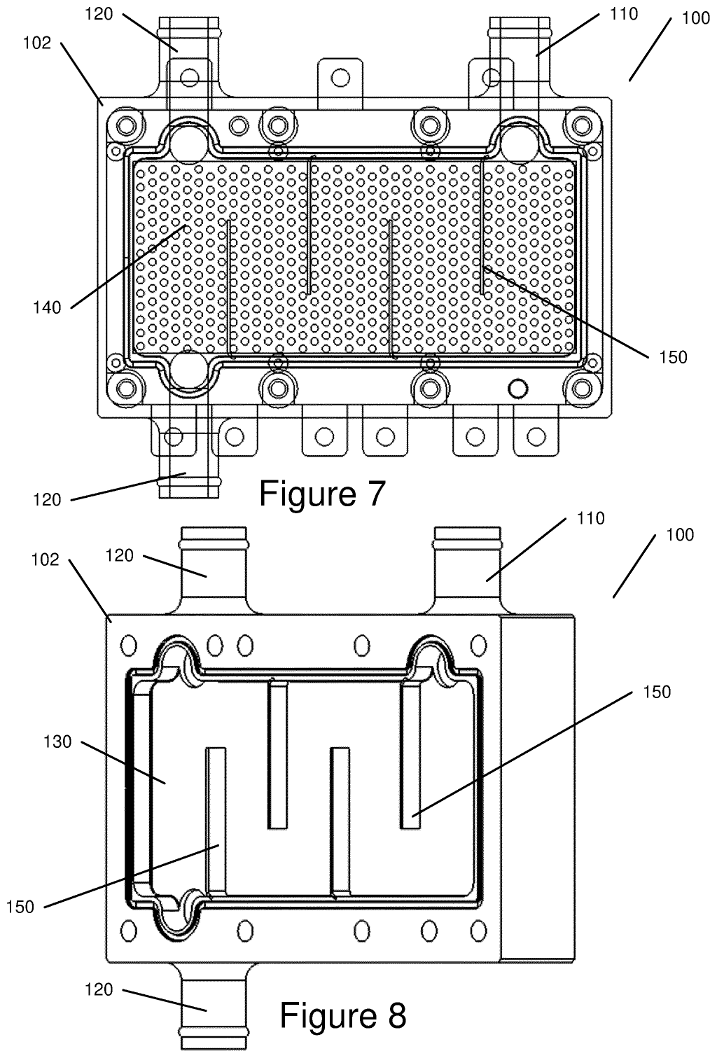

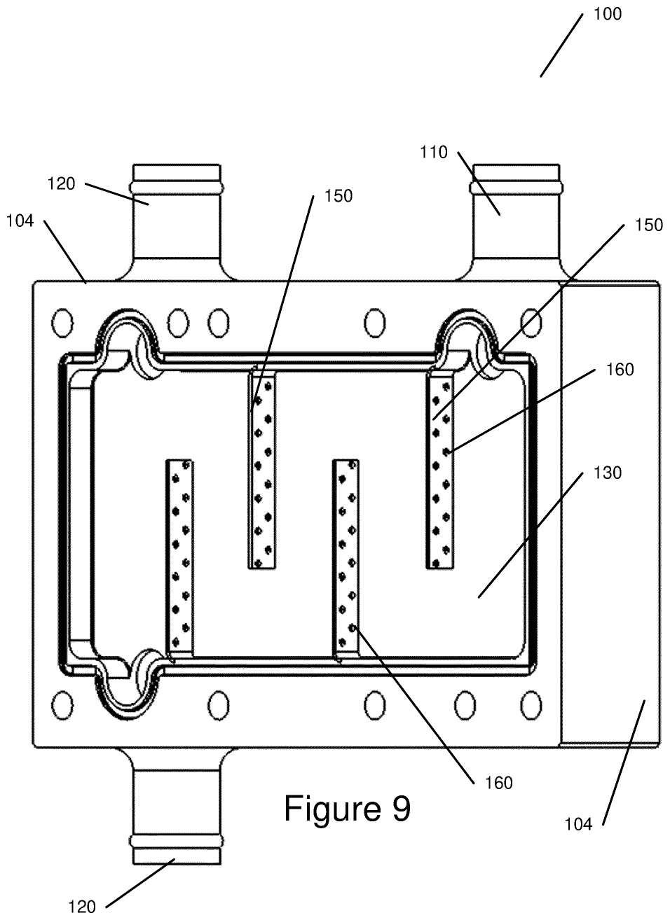

FIGS. 7 and 8 show an example cooling arrangement that incorporates a number of baffles (150). The example shown in the figures comprises four baffles, but this number could be as few as one, or more, depending on the application. Whilst this arrangement is shown having two outlet (120), these are shown for the sake of convenience. In practice, the cooling arrangement is either run as a “U”-shaped flow arrangement, where the inlet (110) and outlet (120) are on the same side (i.e. the same side wall (104) or in the capping plate (108)), or in the diagonal arrangement, where the inlet (110) and outlet (120) are in opposing side walls, diagonally opposed from one another.

The baffles are plates extending between the back plate (106) and capping plate (108), and extending from one or another side wall (104) a portion of the way into the cavity between the side walls (104). Typically, the baffles (150) comprise aluminium sheet metal or alloy or some similar high thermal conductivity material with production fabrication properties.

The purpose of the baffles (150) is to cause the cooling fluid flowing between the inlet (110) and outlet (120) to meander back and forth through the cavity as it flows between the inlet (110) and outlet (120). This is the case whether the cooling arrangement is arranged as a “U”-shaped flow arrangement, or as a diagonal flow arrangement, as discussed above.

In causing the cooling fluid to meander through the cavity, a surprising advantage is that this arrangement is capable of extracting more heat from the pin fins (140) than above-mentioned arrangements without the baffles. This is the case whether the cooling arrangement utilises the “U”-shaped flow arrangement, or the diagonal flow arrangement.

However, a disadvantage of this arrangement is that the baffles (150) increase the pressure drop experienced by the cooling fluid as it flows between the inlet (110) and outlet (120). As a consequence of this, the cooling fluid pressure may need to be increased in order to ensure that there is sufficient flow through the cooling arrangement in order to cool the devices mounted to the base plate (106). This may have detrimental consequences with the cooling arrangement if the housing or other components associated with the cooling fluid flow are not pressure rated high enough in order to cope with the increased pressure required to drive the cooling fluid.

A known way of addressing this problem is by providing a clearance gap between pin-fin tips and the capping plate such that coolant may bypass the pin fins to relieve pressure. However, coolant so by-passing pin-fins does not maximise cooling capacity of the system and does not aid in the mixing of fluids at different temperatures.

FIG. 9 shows a cooling arrangement that addresses the disadvantages associated with the arrangements discussed in FIGS. 7 and 8. Features in common with the earlier arrangements are given the same reference numerals.

As with the arrangement of FIGS. 7 and 8, FIG. 9 shows an example cooling arrangement that incorporates a number of baffles (150). The example shown in the figures comprises four baffles, but this number could be a few as one, or more, depending on the application. Whilst this arrangement is shown having two outlets (120), these are shown for the sake of convenience. In practice, the cooling arrangement is either run as a “U”-shaped flow arrangement, where the inlet (110) and outlet (120) are on the same side (i.e. the same side wall (104) or in the capping plate (108)), or in the diagonal arrangement, where the inlet (110) and outlet (120) are in opposing side walls, diagonally opposed from one another.

The baffles are plates extending between the back plate (106) and capping plate (108), and extending from one or another side wall (104) a portion of the way into the cavity between the side walls (104). Typically, the baffles (150) comprise aluminium sheet metal or alloy or some similar high thermal conductivity material with production fabrication properties. Baffles may be thermally attached to the side walls (104), the back plate (106), the capping plate (108) or more than one of these.

The purpose of the baffles (150) is to cause the cooling fluid flowing between the inlet (110) and outlet (120) to meander back and forth through the cavity as it flows between the inlet (110) and outlet (120). This is the case whether the cooling arrangement is arranged as a “U”-shaped flow arrangement, or as a diagonal flow arrangement, as discussed above.

In order to address the increased pressure differential experienced by an arrangement comprising the baffles, one or more through holes (160) are provided in at least one of the baffles (150). These through holes (160) permit a portion of the meandering cooling fluid flowing between the inlet (110) and outlet (120) to pass through the baffle (150) instead of forcing all of the cooling fluid to flow around the baffle (150).

The shape of holes in baffles may be circular or “star” shaped (or any other shape) to improve heat transfer and turbulence. Holes may be arranged in a regular array. The holes may be situated approximately one-hole diameter up from the base plate. A second array of holes may be arranged offset from, or in line with, the first set of holes. Hole diameters are preferably less than one half the height of baffle plates.

Surprisingly it has been found that the pressure difference experienced by the cooling fluid flowing between the inlet (110) and outlet (120) is significantly and usefully reduced compared to the arrangement shown in FIGS. 7 and 8.

Moreover, it has been found that incorporating the through holes (160) in one or more of the baffles (150) leads to an improvement in the cooling performance when compared to any of the above-described arrangements. As such, this arrangement is superior in its ability to extract heat from the pins (and thus the power devices thermally coupled to the base plate (106)) compared to the arrangements discussed in FIGS. 1 to 8.

The improved heat transfer is thought to be because
a) heat transferred from pin-fins to coolant is improved because coolant can pass through holes in baffles via turbulent flow and so homogenises coolant temperature in the next baffle section whilst turbulence improving the capacity of coolant to remove heat from pin-fins and
b) because baffles are themselves high thermal conductivity conduits of heat from the base plate and holes in baffles increases heat transfer to coolant fluid.

A configuration of through holes in baffles combined with by-pass flow between baffles, wherein baffles and pin-fins stop short of the capping plate (similar to that discussed above with reference to the gaps between the pin tops and capping place) is also possible. There is a surprising further advantage in providing this arrangement in allowing coolant to flow between pin-fin tips and the capping plate, in generally linear flow format, which provides a “cool” fluid heat sink for “hot” turbulent coolant from baffle through holes and pin-fins, to blend with.

No doubt many other effective alternatives will occur to the skilled person. It will be understood that the invention is not limited to the described embodiments and encompasses modifications apparent to those skilled in the art lying within the scope of the claims appended hereto.

1. A cooling arrangement, comprising:
a housing having a base plate, side walls around the periphery of the base plate, and a capping plate opposing the base plate, the base plate, side walls and capping plate being arranged to form a fluid-tight cavity through which a cooling fluid is flowable;
an array of pins fins protruding from the base plate into the cavity;
an inlet and an outlet in fluid communication with the cavity, the inlet and outlet being arranged such that cooling fluid flowing between the inlet and outlet is caused to flow through the cavity over the array of pin fins; and
one or more baffles extending between the base plate and capping plate, and extending along a portion of the base plate between opposing side walls for providing a labyrinthine flow path for the cooling fluid when flowing through the cavity between the inlet and outlet, wherein at least one of the baffles comprises at least one through hole, through which cooling fluid is flowable from one side of the baffle to the other.

2. The cooling arrangement according to claim 1, comprising a plurality of through holes in the respective baffle, the holes being arranged in an array along at least a portion of the length of the baffle.

3. The cooling arrangement according to claim 2, wherein the array of through holes comprises two or more rows of through holes.

4. The cooling arrangement according to claim 3, wherein the rows of through holes are offset from one another.

5. The cooling arrangement according to claim 1, wherein the inlet and outlet are located in the same sidewall of the housing, or the inlet and outlet are located in the capping plate, opposing the base plate.

6. The cooling arrangement according to claim 1, wherein the inlet is located in a first side wall, and the outlet is located in a second side wall, different to the first side wall.

7. The cooling arrangement according to claim 6, wherein the first and second side walls oppose one another.

8. The cooling arrangement according to claim 7, wherein the inlet and outlet diagonally oppose one another.

9. The cooling arrangement according to claim 1, wherein the pin fins are mounted on and thermally coupled to the base plate.

10. The cooling arrangement according to claim 1, wherein the pin fins extend from the base plate a portion of the distance towards the capping plate, wherein a gap is provided between the tip of the pin fins and the capping plate.

11. The cooling arrangement according to claim 1, wherein the pin fins are cylindrical or tapered cylindrical.

12. The cooling arrangement according to claim 1, wherein a gap is provided between the capping plate and at least one of the baffles along at least a portion of the length of the baffle.

13. The cooling arrangement according to claim 1, wherein the through holes are generally circular or star shaped.
